(19) United States
(12) Patent Application Publication
(10) Pub. No.: US 2020/0087851 A1
(43) Pub. Date: Mar. 19, 2020

(54) SYSTEM AND METHOD FOR THE PRODUCTION AND TREATMENT OF FUR, SKIN, AND LEATHER COMMODITIES

(71) Applicant: Furs Ltd., George Town (KY)

(72) Inventor: Scott RUBMAN, Buenos Aires (AR)

(21) Appl. No.: 16/572,140

(22) Filed: Sep. 16, 2019

Related U.S. Application Data
(60) Provisional application No. 62/732,289, filed on Sep. 17, 2018.

(51) Int. Cl. D06M 11/74; D06M 11/83; D06M 19/00; H01L 29/66

(52) U.S. Cl. CPC D06M 11/74; D06M 11/83; D06M 13/53; H01L 29/66015; D06M 19/00

(57) ABSTRACT

A semi-metal or other semiconductor material is applied to a portion of a fur, skin, or feather commodity. The material is applied in a liquid, aerosol, or adhesive formulation, such that the material is molecularly adhered to the fur, skin, or feather commodity. The material may also be applied by a laser burning or branding process. The material may be applied prior to a chemical treatment of the fur, skin, or feather commodity.

### CROSS REFERENCE TO RELATED APPLICATION

This application claims the benefit of U.S. Provisional Patent Application No. 62/732,289, filed on Sep. 17, 2018, the disclosure of which is incorporated by reference herein in its entirety.

### FIELD OF INVENTION

The present disclosure is directed to a system and method of treating a portion of a fur, skin, or leather commodity to facilitate identification. In another embodiment, the present disclosure is directed to a system and method of producing fur, skin, or leather commodities.

### BACKGROUND

The business-to-business side of the fur industry involves the purchase of fur pelts for the manufacture of garments or other articles. Likewise, the business-to-business side of the leather industry involves the purchase of leather skins for the manufacture of garments or articles. Fur pelts and leather skins are typically available in limited supply from fur farmers, ranchers, or trappers, and may be of varying quality. A purchaser may determine the quality of the pelts or skins through personal inspection, or through verification by a trusted seller or intermediary. Therefore, the business-to-business side of the fur and leather industries is primarily conducted in a face-to-face auction environment on limited occasions. Such auctions require purchasers to travel to locations throughout the world to procure raw product. Alternatively, the purchaser may engage an agent or purchase pelts or skins from a broker (or a chain of intermediaries) that purchased the pelts or skins through an auction or a private treaty with particular farmers, ranchers, or trappers. A manufacturer may also purchase pelts or skins directly from a farmer, rancher, or trapper.

The manufacturer then manufactures garments or other articles and may sell the articles to department stores, independent stores, or leased facilities. The manufacturer may sell the articles through a supply chain of distributors. Alternatively, the manufacturer may sell directly to consumers. The consumer can determine the quality and authenticity of the garment through a visual inspection or by trusting the representations of the seller.

Prior patent applications, including U.S. Provisional Patent Application No. 62/299,096, U.S. patent application Ser. No. 15/441,755, and International Patent Application No. PCT/US2017/047774 are directed to a platform and data repository for fur, skin, or feather commodities (such as leather skins and other hides or skins, including reptile skin, fish skin, ostrich skin, and bird feathers). More particularly, those applications are directed to a platform and repository that provide for the digital identification and the adjudication of the provenance of fur pelts and articles or leather goods based upon and backed up by DNA. Each of those patent applications are incorporated by reference herein in their entirety.

To facilitate identification of fur, skin, or feather commodities, a need exists to protect at least a portion of the commodity during chemical treatments to preserve DNA within that commodity. A need further exists to mark or tag fur, skin, or feather commodities while preserving the look, feel, and quality of the commodity. Commodities that have been protected or marked may be identified and tracked in an above described platform and data repository. However, such protection and marking may be done independently of any platform or data repository.

Additionally, a need exists to produce fur, skin, or feather commodities independently of a living animal.

### SUMMARY OF THE INVENTION

In one embodiment, a semiconductor material is applied to a portion of a fur, skin, or feather commodity. The material is applied in a liquid, aerosol, or adhesive formulation, such that the material is molecularly adhered to (or adsorbed by) the fur, skin, or feather commodity. Alternatively, the material may be applied by a laser burning or branding process. The material may be applied prior to a chemical treatment of the fur, skin, or feather commodity.

In another embodiment, a molecular adsorbing system is capable of transmitting or receiving digital certification information in either a liquid, aerosol or adhesive format. The material may include but is not limited to graphene.

In another embodiment, a fur, skin, or feather commodity is produced by an additive manufacturing process. In one such embodiment, skin is created through a 3D bioprinting process. Hair or feathers are then grafted onto the bioprinted skin.

### BRIEF DESCRIPTION OF THE DRAWINGS

In the accompanying drawings, structures are illustrated that, together with the detailed description provided below, describe exemplary embodiments of the claimed invention. Like elements are identified with the same reference numerals. It should be understood that elements shown as a single component may be replaced with multiple components, and elements shown as multiple components may be replaced with a single component. The drawings are not to scale and the proportion of certain elements may be exaggerated for the purpose of illustration.

FIG. 1 is a schematic drawing illustrating the application of a material to a skin, feather, or fur commodity; and

FIG. 2 is a schematic drawing illustrating a bioprinting system and process.

### DETAILED DESCRIPTION

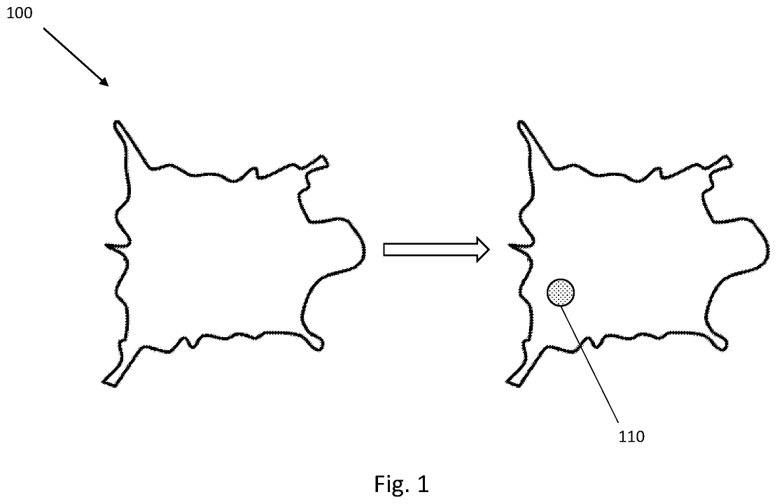

FIG. 1 is a schematic drawing illustrating the application of a material to a skin or fur commodity. In the illustrated embodiment, a fur commodity 100 is provided. In alternative embodiments, a skin (such as leather skins or other hides or skins, including reptile, fish and ostrich skin) or feather commodity may be provided. While the process below is described in the context of a fur commodity, it should be understood that the process may be similarly employed for a skin or feather commodity.

A material 110 is applied to at least a portion of the fur commodity 100. While FIG. 1 shows a visible, circular region of material 110, it should be understood that this is merely for illustrative purposes. The material may be applied to a polygonal or irregular shaped region of the fur commodity. The region may be small, so as not to be easily noticeable or even visible at all. Alternatively, the region may be larger, even encompassing the entire fur commodity.

The material 110 may be applied to the fur commodity 100 in several different ways. In one embodiment, the material 110 is applied in a solid form or in a liquid state. such that the material is molecularly adhered to (or adsorbed by) the fur, skin, or feather commodity. For example, the material 110 aerosol or adhesive formulation. Alternatively, the material 110 may be applied by a laser burning or branding process.

In one embodiment, the material 110 is a conductive material capable of storing electricity, and thus capable of storing digital information. The material 110 may be a semi-metal or other semiconductor material. In one specific embodiment, the material is a zero-gap semiconductor. Exemplary properties of the material 110 may include, without limitation, a valley degeneracy of gv=2, electron mobility greater than 15,000 cm²×V⁻¹×s⁻¹, and resistivity of less than 10⁻⁶ ohm-cm. One specific example of the material 110 is graphene. However, it should be understood that the material may be a non-metal.

The material 110 may be selected such that is molecularly adhered to (or adsorbed by) the fur commodity 100. In other words, the material 110 adheres to the surface of the fur commodity 100 without dissolving or permeating into the fur commodity 100. Thus, the material 110 forms a protective layer over the portion of the fur commodity 100, and may preserve underlying DNA during any chemical, thermal, or other treatment of the fur commodity. Thus, if DNA testing of the fur commodity 100 is desired at a later time, the material 110 may be removed and DNA may be extracted.

The electrical properties of the material 110 may also allow the transmission and storage of digital information. Digital information, such as digital certification information may be embedded into the material 110 and may be transmitted through a scanning process. Thus, the fur commodity 100 and material 110 may be characterized as a molecular adsorbing system that is capable of transmitting or receiving digital certification information in either a liquid, aerosol or adhesive format.

In an some embodiments, the material 110 is not capable of storing digital information, but still protects the fur commodity 100 from experiencing DNA damage. In such an embodiment, the material 110 may be used in conjunction with an RFID or other device capable of storing and transmitting data.

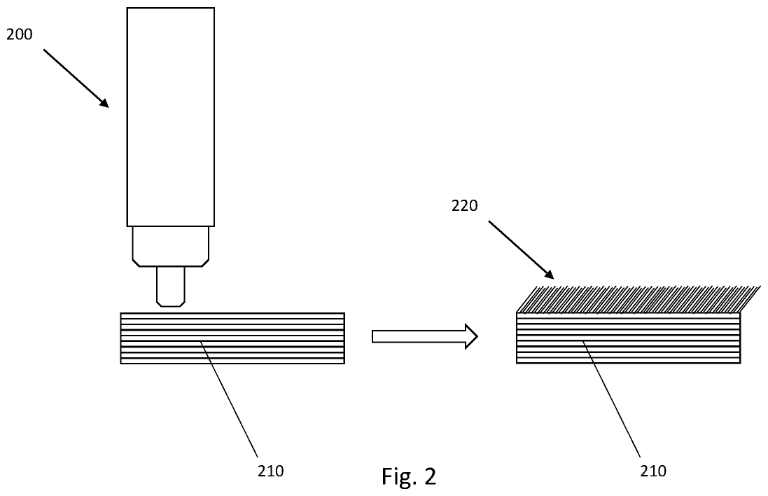

FIG. 2 is a schematic drawing illustrating a bioprinting process. A 3D bioprinter 200 extrudes layers of biomaterials and living cells 210 to make biometric skin. The skin cells may include, without limitation, melanocytes, keratinocytes, and fibroblasts. Alternatively, or in addition, stem cells may be employed. Multiple layers of biomaterials and living cells may be overlaid until a biometric skin of desired thickness has been produced.

After the biometric skin is produced, hair or feathers are shorn from an animal and grafted onto the biometric skin. The hair or feathers may also be grated or planted onto the biometric skin, similar to a process of planting seeds in soil. The hair or feathers then grow on the biometric skin.

In one embodiment, the biomaterials and living cells used to produce the biometric skin are from the same animal that is shorn of hair or feathers. In another embodiment, the biomaterials and living cells used to produce the biometric skin are from a different animal that is shorn of hair or feathers. In this embodiment, the animals may be from the same species or from different species.

In an alternative embodiment, synthetic skin is produced without living cells.

While the present disclosure has been illustrated by the description of embodiments thereof, and while the embodiments have been described in considerable detail, it is not the intention of the applicants to restrict or in any way limit the scope of the appended claims to such detail. Additional advantages and modifications will readily appear to those skilled in the art. Therefore, the disclosure, in its broader aspects, is not limited to the specific details, the representative apparatus and method, and illustrative examples shown and described. Accordingly, departures may be made from such details without departing from the spirit or scope of the applicant's general inventive concept.

To the extent that the term “includes” or “including” is used in the specification or the claims, it is intended to be inclusive in a manner similar to the term “comprising” as that term is interpreted when employed as a transitional word in a claim. Furthermore, to the extent that the term “or” is employed (e.g., A or B) it is intended to mean “A or B or both.” When the applicants intend to indicate “only A or B but not both” then the term “only A or B but not both” will be employed. Thus, use of the term “or” herein is the inclusive, and not the exclusive use. See, Bryan A. Garner, A Dictionary of Modern Legal Usage 624 (2d. Ed. 1995). Also, to the extent that the terms “in” or “into” are used in the specification or the claims, it is intended to additionally mean “on” or “onto.” Furthermore, to the extent the term “connect” is used in the specification or claims, it is intended to mean not only “directly connected to,” but also “indirectly connected to” such as connected through another component or components.

What is claimed is:

1. A method of treating a fur, skin, or feather commodity, the method comprising:
providing a fur, skin, or feather commodity; and
applying a semiconductor material to a portion of a fur, skin, or feather commodity, such that the material is molecularly adhered to the fur, skin, or feather commodity.

2. The method of claim 1, wherein the semiconductor material is a zero-gap semiconductor.

3. The method of claim 1, wherein the semiconductor material has a valley degeneracy of gv=2.

4. The method of claim 1, wherein the semiconductor material has electron mobility greater than 15,000 cm²×V⁻¹×s⁻¹.

5. The method of claim 1, wherein the semiconductor material has resistivity of less than 10⁻⁶ ohm-cm.

6. The method of claim 1, wherein the semiconductor material is graphene.

7. The method of claim 1, wherein the wherein the semiconductor material is applied in a liquid state.

8. The method of claim 1, wherein the wherein the semiconductor material is applied in a solid state.

9. The method of claim 1, wherein the wherein the semiconductor material is applied as an aerosole.

10. The method of claim 1, further comprising a step of storing digital information on the semiconductor material.

11. A method of testing DNA of a fur, skin, or feather commodity, the method comprising:
providing a fur, skin, or feather commodity;
applying a semiconductor material to a portion of a fur, skin, or feather commodity;
treating the fur, skin, or feather commodity;
removing the semiconductor material from the portion of the fur, skin, or feather commodity;
extracting DNA from the portion of the fur, skin, or feather commodity; and
testing the extracted DNA.

12. The method of claim 11, wherein the semiconductor material is applied such that the material is molecularly adhered to the fur, skin, or feather commodity.

13. The method of claim 11, wherein the semiconductor material has a valley degeneracy of gv=2.

14. The method of claim 11, wherein the semiconductor material has electron mobility greater than 15,000 cm²×V⁻¹×s⁻¹.

15. The method of claim 11, wherein the semiconductor material has resistivity of less than 10⁻⁶ ohm-cm.

16. The method of claim 11, wherein the semiconductor material is graphene.

17. The method of claim 11, wherein the treating of the fur, skin, or feather commodity includes heat treating the fur, skin, or feather commodity.

18. The method of claim 11, wherein the treating of the fur, skin, or feather commodity includes chemical treating the fur, skin, or feather commodity.

19. The method of claim 11, wherein the semiconductor material is applied as an adhesive formulation.

20. A method of producing a fur, skin, or feather commodity, the method comprising:
forming layers of skin through a 3D bioprinting process; and
grafting hair or feathers onto the bioprinted skin.
